(19) United States
(12) Patent Application Publication
(10) Pub. No.: US 2025/0063799 A1
(43) Pub. Date: Feb. 20, 2025

(54) SEMICONDUCTOR DEVICES AND METHODS OF FABRICATING THE SAME

(71) Applicant: Samsung Electronics Co., Ltd., Suwon-si (KR)

(72) Inventors: Ju Hun PARK, Suwon-si (KR); Jong Hyun PARK, Suwon-si (KR); Jong Lae LEE, Suwon-si (KR); Jong Sun LEE, Suwon-si (KR); Da Un JEON, Suwon-si (KR); Hyo Won JEONG, Suwon-si (KR); Gyu Eon CHO, Suwon-si (KR); Hyo Taek CHOI, Suwon-si (KR); Soo Yeon HONG, Suwon-si (KR)

(21) Appl. No.: 18/619,655

(22) Filed: Mar. 28, 2024

(30) Foreign Application Priority Data
Aug. 17, 2023 (KR) 10-2023-0107441

(51) Int. Cl. H01L 29/417; H01L 23/522; H01L 23/528; H01L 27/088; H01L 29/78

(52) U.S. Cl. CPC H01L 29/41775; H01L 23/5226; H01L 23/5283; H01L 23/5286; H01L 27/0886; H01L 29/7855

(57) ABSTRACT

A semiconductor device includes: an active pattern extending in a first direction across an underlying substrate, a gate structure extending in a second direction, on the active pattern, a first source/drain contact electrically connected to a source/drain region within the active pattern, on one side of the gate structure, and a first via pattern electrically connected to an upper surface of the first source/drain contact. A rail pattern is provided, which extends in the first direction, and is spaced apart from the first via pattern in the second direction. A wiring pattern extends in the first direction, and is electrically connected to an upper surface of the rail pattern. The first source/drain contact includes a first recess therein, which is more recessed downwardly relative to the upper surface of the first source/drain contact, and at least a portion of the first recess extends adjacent to the rail pattern.

### REFERENCE TO PRIORITY APPLICATION

This application claims priority under 35 U.S.C. 119 to Korean Patent Application No. 10-2023-0107441, filed Aug. 17, 2023, the disclosure of which is hereby incorporated herein by reference.

### BACKGROUND

The present disclosure relates to integrated circuit devices and methods of fabricating the same and, more particularly, to semiconductor devices including source/drain contacts and methods of fabricating the same.

Due to characteristics such as miniaturization, multi-functionality, and/or lower fabricating cost, semiconductor devices have received attention as important factors in an electronic industry. Semiconductor devices may be classified into semiconductor memory devices that store logical data, semiconductor logical devices that arithmetically process the logical data, and hybrid semiconductor devices that include both memory and logical devices.

As the electronic industry becomes more highly developed, demands for the characteristics of the semiconductor devices are rapidly increasing, and include demands for higher reliability, higher speed, and/or higher multi-functionality. In order to satisfy these required characteristics, the structures in the semiconductor devices have become increasingly complex and highly integrated.

### SUMMARY

Aspects of the present disclosure provide semiconductor devices having improved performance.

Aspects of the present disclosure also provide methods of fabricating semiconductor devices having improved performance, reliability and yield.

According to an aspect of the present disclosure, there is provided a semiconductor device including: an active pattern extending in a first direction on an underlying substrate, a gate structure extending in a second direction intersecting the first direction on the active pattern, a first source/drain contact connected to a source/drain region of the active pattern on one side of the gate structure, a first via pattern connected to an upper surface of the first source/drain contact, a rail pattern extending in the first direction and spaced apart from the first via pattern in the second direction, and a wiring pattern extending in the first direction and connected to an upper surface of the rail pattern. The first source/drain contact includes a first recess that is recessed more downwardly than the upper surface of the first source/drain contact, and at least a portion of the first recess is adjacent to the rail pattern.

According to a further aspect of the present disclosure, there is provided a semiconductor device including: a substrate, a first active pattern extending in a first direction on the substrate, a gate structure extending in a second direction intersecting the first direction on the first active pattern, a first source/drain contact connected to a first source/drain region of the first active pattern on one side of the gate structure, a first via pattern connected to an upper surface of the first source/drain contact, a rail pattern extending in the first direction and connected to a side surface of the first pattern, and a wiring pattern extending in the first direction and connected to an upper surface of the rail pattern. In addition, the first source/drain contact includes a first recess recessed more downwardly than the upper surface of the first source/drain contact.

According to another aspect of the present disclosure, there is provided a semiconductor device including: a substrate, a first active pattern extending in a first direction on the substrate, a gate structure extending in a second direction intersecting the first direction on the first active pattern, a first source/drain region in the first active pattern on both sides of the gate structure, a first interlayer insulating film covering the gate structure and the first source/drain region on the substrate, a first source/drain contact penetrating through the first interlayer insulating film on one side of the gate structure and connected to the first source/drain region, a second source/drain contact penetrating through the first interlayer insulating film on the other side of the gate structure and connected to the first source/drain region, an etch stop layer covering an upper surface of the first interlayer insulating film, an upper surface of the first source/drain contact, and an upper surface of the second source/drain contact, a second interlayer insulating film on the etch stop layer, a first via pattern penetrating through the etch stop layer and the second interlayer insulating film and connected to the upper surface of the first source/drain contact, a second via pattern penetrating through the etch stop layer and the second interlayer insulating film and connected to the upper surface of the second source/drain contact, a first rail pattern extending in the first direction on the etch stop layer and a first power wiring extending in the first direction on the second interlayer insulating film and connected to an upper surface of the first rail pattern. In some embodiments, the first via pattern is spaced apart from the first rail pattern in the second direction, the second via pattern is connected to a side surface of the first rail pattern, the first source/drain contact includes a first recess that is recessed more downwardly than the upper surface of the first source/drain contact, and the second source/drain contact includes a second recess that is recessed more downwardly than the upper surface of the second source/drain contact.

Nonetheless, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic layout view for describing a semiconductor device according to some example embodiments.

FIG. 2 is a cross-sectional view taken along line A-A of FIG. 1.

FIG. 3 is a cross-sectional view taken along line B-B of FIG. 1.

FIG. 4 is a cross-sectional view taken along line C-C of FIG. 1.

FIG. 5 is an enlarged view for describing an area R1 of FIG. 4.

FIG. 6 is a cross-sectional view taken along line D-D of FIG. 1.

FIG. 7 is an enlarged view for describing area R2 of FIG. 6.

FIGS. 8 and 9 are other various enlarged views for describing the R2 region of FIG. 6.

FIG. 10 is another cross-sectional view taken along line A-A of FIG. 1.

FIG. 11 is another cross-sectional view taken along line B-B of FIG. 1.

FIG. 12 is a schematic layout view for describing a semiconductor device according to some example embodiments.

FIG. 13 is a cross-sectional view taken along line E-E of FIG. 12.

FIG. 14 is a schematic layout view for describing a semiconductor device according to some example embodiments.

FIG. 15 is a cross-sectional view taken along line F-F of FIG. 14.

FIG. 16 is a schematic layout view for describing a semiconductor device according to some example embodiments.

FIG. 17 is a cross-sectional view taken along line G-G of FIG. 16.

FIGS. 18 to 29 are intermediate step views for describing a method for fabricating a semiconductor device according to some example embodiments.

### DETAILED DESCRIPTION OF EMBODIMENTS

It will be understood that, although the terms first, second, etc. may be used herein to describe various elements or components, these elements or components should not be limited by these terms. These terms are only used to distinguish one element or component from another element or component. Therefore, a first element or component mentioned below could be termed a second element or component without departing from the teachings of the present inventive concept.

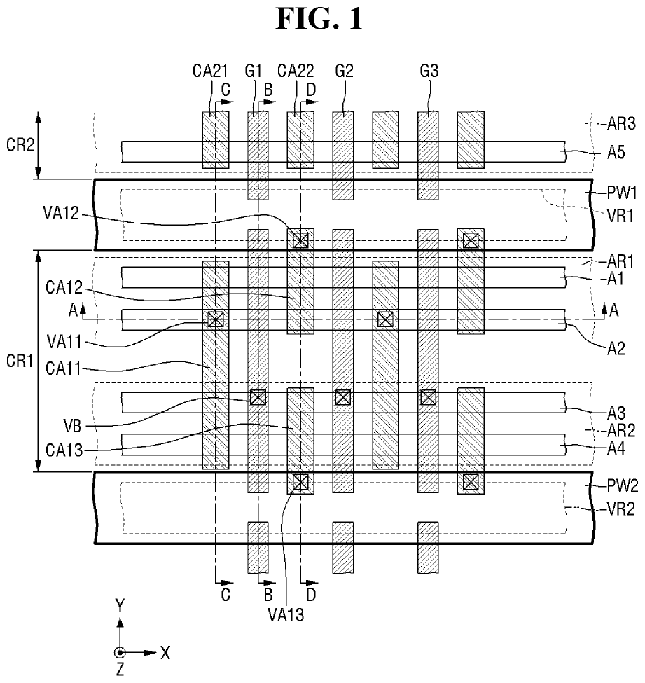

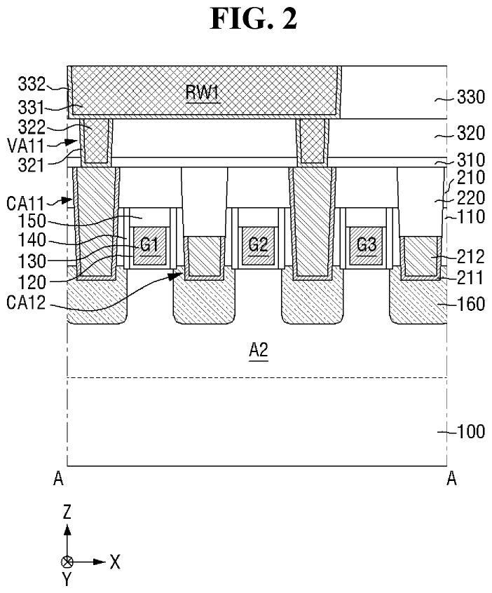

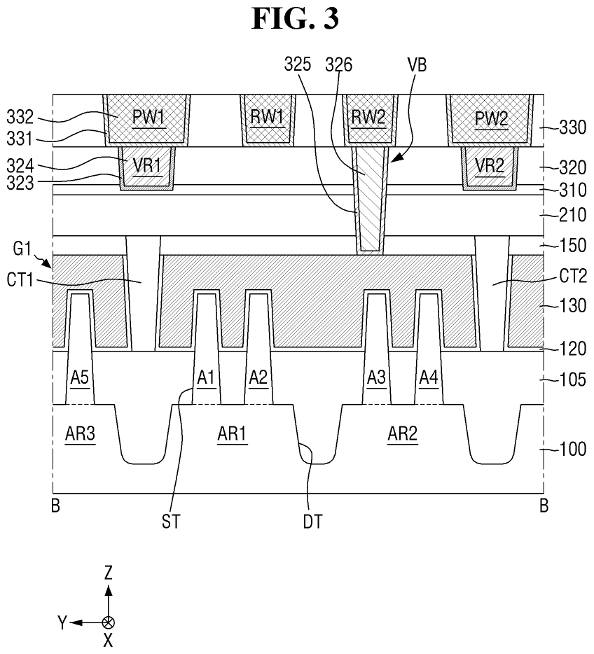

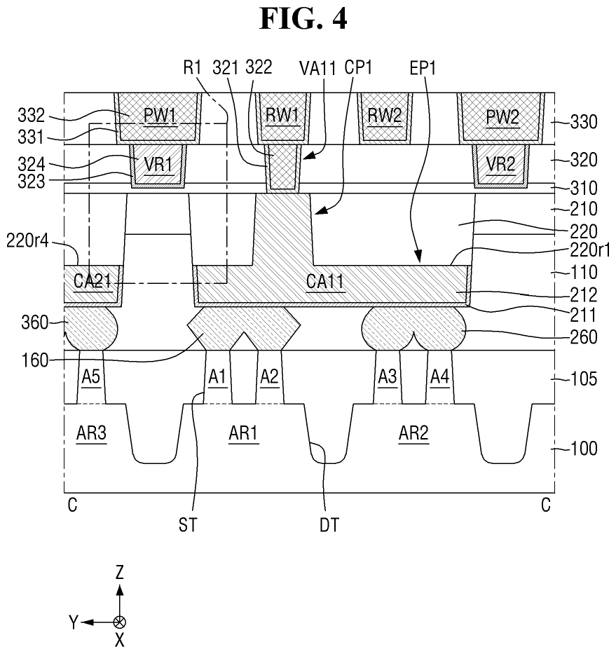

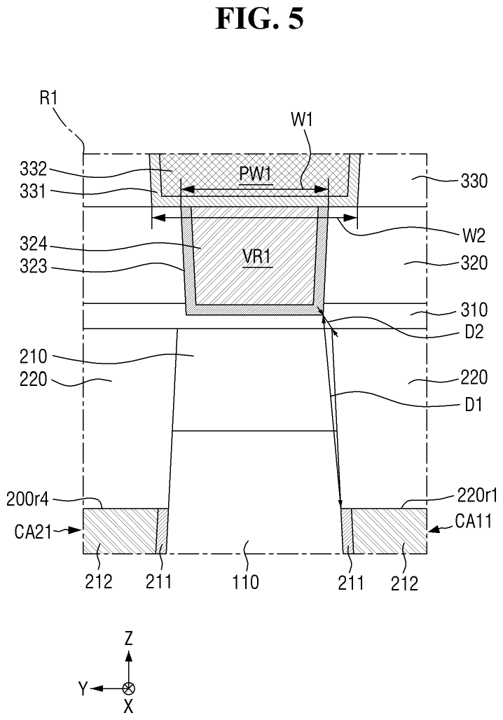

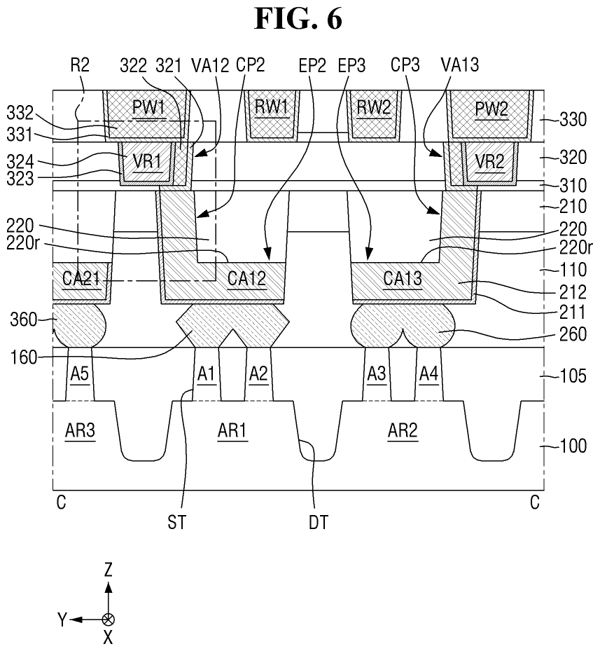

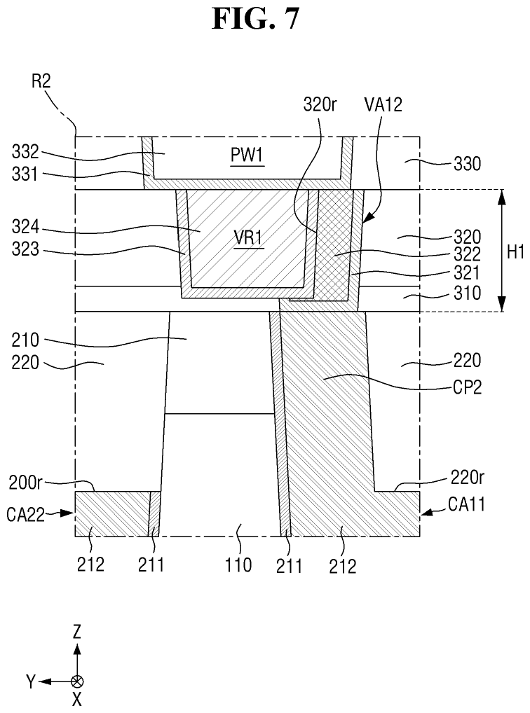

A semiconductor device according to example embodiments will be described below with reference to FIGS. 1 to 17. FIG. 1 is a schematic layout view for describing a semiconductor device according to some example embodiments; FIG. 2 is a cross-sectional view taken along line A-A of FIG. 1; FIG. 3 is a cross-sectional view taken along line B-B of FIG. 1; FIG. 4 is a cross-sectional view taken along line C-C of FIG. 1; FIG. 5 is an enlarged view for describing an area R1 of FIG. 4; FIG. 6 is a cross-sectional view taken along line D-D of FIG. 1; and FIG. 7 is an enlarged view for describing area R2 of FIG. 6.

Referring to FIGS. 1 to 7, a semiconductor device according to some example embodiments may include a first cell region CR1 and a second cell region CR2. The first cell region CR1 and the second cell region CR2 are spaced apart from each other. For example, the first cell region CR1 and the second cell region CR2 may each extend in a first direction X, and may be spaced apart from each other in a second direction Y intersecting the first direction X.

Semiconductor devices may be provided in the first cell region CR1 and the second cell region CR2, respectively. Examples of the semiconductor devices provided in the first cell region CR1 and the second cell region CR2 may include various logic elements such as inverters, AND gates, OR gates, NAND gates, NOR gates, and XOR gates, or static random access memory (SRAM) elements, but are not limited thereto.

The semiconductor device according to some example embodiments may include a substrate 100, active patterns A1 to A5, gate structures G1 to G3, source/drain regions 160, 260, and 360, a first interlayer insulating film 110, a second interlayer insulating film 210, source/drain contacts CA11 to CA22, an etch stop layer 310, a third interlayer insulating film 320, a gate contact VB, via patterns VA11 to VA13, rail patterns VR1 and VR2, inter-wiring insulating film 330, and wiring patterns PW1, PW2, RW1, and RW2. The number and arrangement of active patterns A1 to A5, gate structures G1 to G3, source/drain contacts CA11 to CA22, gate contact VB, via patterns VA11 to VA13, rail patterns VR1 and VR2, and wiring patterns PW1, PW2, RW1, and RW2 are only examples and are not limited to those illustrated.

The substrate 100 may be bulk silicon or silicon-on-insulator (SOI). Unlike this, the substrate 100 may be a silicon substrate, or may include other materials, for example, silicon germanium, silicon germanium on insulator (SGOI), indium antimonide, lead tellurium compounds, indium arsenide, indium phosphate, gallium arsenide, or gallium antimonide, but is not limited thereto.

The substrate 100 may include a first active region AR1, a second active region AR2, and a third active region AR3. The first active region AR1 and the second active region AR2 may be disposed within the first cell region CR1, and the third active region AR3 may be disposed within the second cell region CR2. The first active region AR1, the second active region AR2, and the third active region AR3 may be spaced apart from each other and extend parallel to each other in the first direction X.

In some example embodiments, semiconductor devices (e.g., transistors) of different conductive types may be formed on the first active region AR1 and the second active region AR2. In addition, in some example embodiments, semiconductor devices (e.g., transistors) of different conductivity types may be formed on the first active region AR1 and the third active region AR3. In the following description, it is illustrated that the first active region AR1 is a PFET region, and the second active region AR2 and the third active region AR3 are NFET regions. However, this is only an example, and the first active region AR1 may also be an NFET region, and the second active region AR2 and the third active region AR3 may also be PFET regions.

In some example embodiments, the active regions AR1 to AR3 may be defined by a first trench DT within the substrate 100. The first trench DT may be a deep trench formed within the substrate 100. The first trench DT may extend in the first direction X to separate the active regions AR1 to AR3 from each other.

The active patterns A1 to A5 may be formed on the substrate 100. For example, a first active pattern A1 and a second active pattern A2 may be formed on the first active region AR1, a third active pattern A3 and a fourth active pattern A4 may be formed on the second active region AR2, and a fifth active pattern A5 may be formed on the third active region AR3. The active patterns A1 to A5 may be spaced apart from each other and extend parallel to each other in the first direction X.

In some example embodiments, the active patterns A1 to A5 may be defined by a second trench ST on the active regions AR1 to AR3. The second trench ST may be a shallow trench formed on the active regions AR1 to AR3. The second trench ST may extend in the first direction X to separate the active patterns A1 to A5 from each other. In some example embodiments, each of the active patterns A1 to A5 may include a fin-shaped pattern that protrudes from an upper surface of the substrate 100 and extends in the first direction X.

The active patterns A1 to A5 may each include silicon (Si) or germanium (Ge), which is an elemental semiconductor material. Alternatively, the active patterns A1 to A5 may each include a compound semiconductor, for example, a group IV-IV compound semiconductor or a group III-V compound semiconductor. The group IV-IV compound semiconductor may be, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element. The group III-V compound semiconductor may be, for example, one of a binary compound, a ternary compound, or a quaternary compound formed by combining at least one of aluminum (Al), gallium (Ga), and indium (In), which are group III elements, and at least one of phosphorus (P), arsenic (As), and antimony (Sb), which are group V elements. In the following description, it is illustrated that each of the active patterns A1 to A5 is a silicon (Si) pattern.

In some example embodiments, a field insulating film 105 may be formed on the substrate 100. The field insulating film 105 may surround at least a portion of side surfaces of the active patterns A1 to A5. For example, as illustrated in FIG. 3, a portion of each of the active patterns A1 to A5 may more upwardly protrude than an upper surface of the field insulating film 105. In some example embodiments, the field insulating film 105 may fill at least a portion of the first trench DT and/or the second trench ST. The active regions AR1 to AR3 and the active patterns A1 to A5 may be separated from each other by the field insulating film 105. The field insulating film 105 may include, but is not limited to, for example, at least one of silicon oxide (SiO), silicon oxynitride (SiON), silicon oxycarbonitride (SiOCN), or a combination thereof.

Gate structures G1 to G3 may be formed on the active patterns A1 to A5. Each of the gate structures G1 to G3 may intersect the active patterns A1 to A5. For example, the gate structures G1 to G3 may be spaced apart from each other and extend parallel to each other in the second direction Y.

In some example embodiments, a first gate cutting pattern CT1 and a second gate cutting pattern CT2 for cutting the gate structures G1 to G3 may be formed. The first gate cutting pattern CT1 may extend in the first direction X from one side of the first cell region CR1 (e.g., between the first cell region CR1 and the second cell region CR2) to cut the gate structures G1 to G3. The second gate cutting pattern CT2 may extend in the first direction X from the other side of the first cell region CR1 to cut the gate structures G1 to G3. The first gate cutting pattern CT1 and the second gate cutting pattern CT2 may each include, but are not limited to, for example, at least one of silicon nitride (SiN), silicon oxynitride (SiON), silicon oxycarbonitride (SiOCN), or a combination thereof.

Each of the gate structures G1 to G3 may include a gate dielectric film 120 and a gate electrode 130. The gate dielectric film 120 and the gate electrode 130 may be sequentially stacked on the active patterns A1 to A5.

The gate electrode 130 may include, but is not limited to, for example, at least one of Ti, Ta, W, Al, Co, and a combination thereof. For example, the gate electrode 130 may include silicon or silicon germanium rather than metal.

Although the gate electrode 130 is illustrated as a single film, the teachings of the present inventive concept are not limited thereto. Unlike what is illustrated, the gate electrode 130 may also be formed by stacking a plurality of conductive materials. For example, the gate electrode 130 may include a work function adjusting film for adjusting a work function and a filling conductive film for filling a space formed by the work function adjusting film. The work function adjusting film may include, for example, at least one of TiN, TaN, TIC, TaC, TiAlC, and a combination thereof. The filling conductive film may include, for example, W or Al. The gate electrode 130 may be formed through, for example, a replacement process, but is not limited thereto.

The gate dielectric film 120 may be interposed between each of the active patterns A1 to A5 and the gate electrode 130. For example, the gate dielectric film 120 may conformally extend along a profile of each of the active patterns A1 to A5 protruding from the field insulating film 105. In some example embodiments, a portion of the gate dielectric film 120 may be interposed between the field insulating film 105 and the gate electrode 130. For example, the gate dielectric film 120 may further extend along an upper surface of the field insulating film 105.

In some example embodiments, a portion of the gate dielectric film 120 may be interposed between the gate electrode 130 and the first gate cutting pattern CT1 and between the gate electrode 130 and the second gate cutting pattern CT2. For example, the gate dielectric film 120 may further extend along a side surface of the first gate cutting pattern CT1 and a side surface of the second gate cutting pattern CT2. Unlike what is illustrated, the gate dielectric film 120 may not extend along the side surface of the first gate cutting pattern CT1 and the side surface of the second gate cutting pattern CT2.

The gate dielectric film 120 may include a dielectric material, for example, at least one of silicon oxide, silicon oxynitride, silicon nitride, or a high-k material having a dielectric constant greater than that of silicon oxide. The high-k material may include, but is not limited to, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

The semiconductor device according to some example embodiments may include a negative capacitance (NC) FET using a negative capacitor. For example, the gate dielectric film 120 may include a ferroelectric material film having ferroelectric characteristics and a paraelectric material film having paraelectric characteristics. The ferroelectric material film may have a negative capacitance, and the paraelectric material film may have a positive capacitance. For example, when two or more capacitors are connected in series with each other and the capacitance of each capacitor has a positive value, a total capacitance decreases as compared with a capacitance of each individual capacitor. On the other hand, when at least one of the capacitances of two or more capacitors connected in series with each other has a negative value, the total capacitance may be greater than an absolute value of each individual capacitance while having a positive value.

When the ferroelectric material film having the negative capacitance and the paraelectric material film having the positive capacitance are connected in series with each other, a total capacitance value of the ferroelectric material film and the paraelectric material film connected in series with each other may increase. A transistor including the ferroelectric material film may have a subthreshold swing (SS) less than 60 mV/decade at room temperature, using the increase in the total capacitance value.

The ferroelectric material film may have the ferroelectric characteristics. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may also be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of dopant included in the ferroelectric material film may vary depending on a type of ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y). When the dopant is aluminum (Al), the ferroelectric material film may include 3 to 8 atomic % (at %) of aluminum. Here, a ratio of the dopant may be a ratio of aluminum to the sum of hafnium and aluminum. When the dopant is silicon (Si), the ferroelectric material film may include 2 to 10 atomic % (at %) of silicon. When the dopant is yttrium (Y), the ferroelectric material film may include 2 to 10 at % of yttrium. When the dopant is gadolinium (Gd), the ferroelectric material film may include 1 to 7 at % of gadolinium. When the dopant is zirconium (Zr), the ferroelectric material film may include 50 to 80 at % of zirconium.

The paraelectric material film may have the paraelectric characteristics. The paraelectric material film may include, for example, at least one of silicon oxide and metal oxide having a high dielectric constant. The metal oxide included in the paraelectric material film may include, but is not limited to, for example, at least one of hafnium oxide, zirconium oxide, and aluminum oxide.

The ferroelectric material film and the paraelectric material film may include the same material. The ferroelectric material film may have the ferroelectric characteristics, but the paraelectric material film may not have the ferroelectric characteristics. For example, when the ferroelectric material film and the paraelectric material film include hafnium oxide, a crystal structure of the hafnium oxide included in the ferroelectric material film is different from a crystal structure of the hafnium oxide included in the paraelectric material film.

The ferroelectric material film may have a thickness having the ferroelectric characteristics. The thickness of the ferroelectric material film may be, but is not limited to, for example, 0.5 to 10 nm. Since a critical thickness representing the ferroelectric characteristics may vary for each ferroelectric material, the thickness of the ferroelectric material film may vary depending on the ferroelectric material.

As an example, the gate dielectric film 120 may include one ferroelectric material film. As another example, the gate dielectric film 120 may include a plurality of ferroelectric material films spaced apart from each other. The gate dielectric film 120 may have a stacked film structure in which a plurality of ferroelectric material films and a plurality of paraelectric material films are alternately stacked.

In some example embodiments, each of the gate structures G1 to G3 may further include a gate spacer 140 and a gate capping pattern 150. The gate spacer 140 may be formed on the substrate 100 and the field insulating film 105. The gate spacer 140 may extend along a side surface of the gate electrode 130. In some example embodiments, a portion of the gate dielectric film 120 may be interposed between the gate electrode 130 and the gate spacer 140. For example, the gate dielectric film 120 may further extend along at least a portion of an inner side surface of the gate spacer 140. The gate dielectric film 120 may be formed by a replacement process, but is not limited thereto. The gate spacer 140 may include, but is not limited to, for example, at least one of silicon nitride, silicon oxynitride, silicon oxycarbide, silicon boron nitride, silicon boron carbonitride, silicon oxycarbonitride, and a combination thereof.

The gate capping pattern 150 may extend along an upper surface of the gate electrode 130. For example, the gate capping pattern 150 may cover the upper surface of the gate dielectric film 120 and the upper surface of the gate electrode 130. The gate capping pattern 150 may include, but is not limited to, an insulating material, for example, at least one of silicon nitride, silicon oxynitride, silicon oxycarbide, silicon boron nitride, silicon boron carbonitride, silicon oxycarbonitride, and a combination thereof.

The source/drain regions 160, 260, and 360 may be formed on the active patterns A1 to A5 on the side surfaces of the gate structures G1 to G3. The source/drain regions 160, 260, and 360 may also be formed by doping impurities in the active patterns A1 to A5, and may be epitaxial layers grown from the substrate 100 and/or the active patterns A1 to A5. A first source/drain region 160 may be formed on the first active region AR1. For example, the first source/drain region 160 may be formed in the first active pattern A1 and the second active pattern A2 on both sides of the gate electrode 130. The first source/drain region 160 may be spaced apart from the gate electrode 130 by the gate spacer 140. In some example embodiments, the first source/drain region 160 may include epitaxial layers formed in the first active pattern A1 and the second active pattern A2. In some example embodiments, the first active pattern A1 and the second active pattern A2 may share the first source/drain region 160. For example, the first source/drain region 160 may be an epitaxial layer merged with the first active pattern A1 and the second active pattern A2.

When the semiconductor device formed in the first active region AR1 is a PFET, the first source/drain region 160 may include p-type impurities or impurities to prevent diffusion of p-type impurities. For example, the first source/drain region 160 may include at least one of B, C, In, Ga, Al, and a combination thereof.

A second source/drain region 260 may be formed on the second active region AR2. For example, the second source/drain region 260 may be formed in the third active pattern A3 and the fourth active pattern A4 on both sides of the gate electrode 130. The second source/drain region 260 may be spaced apart from the gate electrode 130 by the gate spacer 140. In some example embodiments, the second source/drain region 260 may include epitaxial layers formed in the third active pattern A3 and the fourth active pattern A4. In some example embodiments, the third active pattern A3 and the fourth active pattern A4 may share the second source/drain region 260. For example, the second source/drain region 260 may be an epitaxial layer merged with the third active pattern A3 and the fourth active pattern A4.

When the semiconductor device formed in the second active region AR2 is an NFET, the second source/drain region 260 may include n-type impurities or impurities to prevent diffusion of n-type impurities. For example, the second source/drain region 260 may include at least one of P, Sb, As, or a combination thereof.

A third source/drain region 360 may be formed on the third active region AR3. For example, the third source/drain region 360 may be formed in the fifth active pattern A5 on both sides of the gate electrode 130. The third source/drain region 360 may be spaced apart from the gate electrode 130 by the gate spacer 140. In some example embodiments, the third source/drain region 360 may include an epitaxial layer formed in the fifth active pattern A5. In some example embodiments, the third source/drain region 360 may include a merged epitaxial layer.

When the semiconductor device formed in the third active region AR3 is an NFET, the third source/drain region 360 may include n-type impurities or impurities to prevent diffusion of n-type impurities. For example, the third source/drain region 360 may include at least one of P, Sb, As, or a combination thereof.

Although the source/drain regions 160, 260, and 360 are each illustrated as a single film, the teachings of the present inventive concept are not limited thereto. For example, the source/drain regions 160, 260, and 360 may each be a multi-film containing different concentrations of impurities.

The first interlayer insulating film 110 and the second interlayer insulating film 210 may be formed on the substrate 100 and the field insulating film 105. The first interlayer insulating film 110 and the second interlayer insulating film 210 may be formed to cover the gate structures G1 to G3 and the source/drain regions 160, 260, and 360. For example, the first interlayer insulating film 110 may be formed on the field insulating film 105. The first interlayer insulating film 110 may cover outer surfaces of the gate structures G1 to G3. In addition, the second interlayer insulating film 210 may be formed on the first interlayer insulating film 110. The second interlayer insulating film 210 may cover an upper surface of the first interlayer insulating film 110 and upper surfaces of the gate structures G1 to G3.

Each of the first interlayer insulating film 110 and the second interlayer insulating film 210 may include, but is not limited to, for example, at least one of silicon oxide, silicon oxynitride, and a low-k material having a dielectric constant lower than that of silicon oxide. The low-k material may include, but is not limited to, for example, at least one of flowable oxide (FOX), torene silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material, and a combination thereof.

The source/drain contacts CA11 to CA22 may be disposed on the side surfaces of the gate structures G1 to G3. The source/drain contacts CA11 to CA22 may be connected to the active patterns A1 to A5. For example, the source/drain contacts CA11 to CA22 may penetrate through the first interlayer insulating film 110 and the second interlayer insulating film 210 and be connected to the source/drain regions 160, 260, and 360.

A first source/drain contact CA11 may be disposed on one side of the first gate structure G1. The first source/drain contact CA11 may penetrate through the interlayer insulating films 110 and 210 and be connected to the first source/drain region 160 and/or the second source/drain region 260. In some example embodiments, the first source/drain contact CA11 may extend in the second direction Y to connect the first source/drain region 160 and the second source/drain region 260.

A second source/drain contact CA12 may be disposed on the other side of the first gate structure G1. For example, the second source/drain contact CA12 may be interposed between the first gate structure G1 and the second gate structure G2. The second source/drain contact CA12 may penetrate through the interlayer insulating films 110 and 210 and be connected to the first source/drain region 160.

A third source/drain contact CA13 may be disposed on the other side of the first gate structure G1. For example, the third source/drain contact CA13 may be interposed between the first gate structure G1 and the second gate structure G2. In addition, the third source/drain contact CA13 may be arranged along the second direction Y with the second source/drain contact CA12. The third source/drain contact CA13 may penetrate through the interlayer insulating films 110 and 210 and be connected to the second source/drain region 260.

A fourth source/drain contact CA21 may be disposed on one side of the first gate structure G1. For example, the fourth source/drain contact CA21 may be arranged along the second direction Y with the first source/drain contact CA11. The fourth source/drain contact CA21 may penetrate through the interlayer insulating films 110 and 210 and be connected to the third source/drain region 360.

A fifth source/drain contact CA22 may be disposed on the other side of the first gate structure G1. For example, the fifth source/drain contact CA22 may be interposed between the first gate structure G1 and the second gate structure G2. In addition, the fifth source/drain contact CA22 may be arranged along the second direction Y with the second source/drain contact CA12 and the third source/drain contact CA13. The fifth source/drain contact CA22 may penetrate through the interlayer insulating films 110 and 210 and be connected to the third source/drain region 360. In some example embodiments, the source/drain contacts CA11 to CA22 may include recesses 220r1 to 220r5 that are more recessed downwardly than upper surfaces of the source/drain contacts CA11 to CA22.

For example, as illustrated in FIG. 4, the first source/drain contact CA11 may include a first extension portion EP1 and a first protruding portion CP1. The first extension portion EP1 may extend in the second direction Y to connect the first source/drain region 160 and the second source/drain region 260. The first protruding portion CP1 may protrude in the third direction Z from an upper surface of the first extension portion EP1. The upper surface of the first extension portion EP1 may define a lower surface of a first recess 220r1, and a side surface of the first protruding portion CP1 may define a side surface of the first recess 220r1.

In addition, for example, as illustrated in FIG. 6, the second source/drain contact CA12 may include a second extension portion EP2 and a second protruding portion CP2. The second extension portion EP2 may extend in the second direction Y and may be connected to the first source/drain region 160. The second protruding portion CP2 may protrude in the third direction Z from an upper surface of the second extension portion EP2. The upper surface of the second extension portion EP2 may define a lower surface of a second recess 220r2, and a side surface of the second protruding portion CP2 may define a side surface of the second recess 220r2.

In addition, for example, as illustrated in FIG. 6, the third source/drain contact CA13 may include a third extension portion EP3 and a third protruding portion CP3. The third extension portion EP3 may extend in the second direction Y and may be connected to the second source/drain region 260. The third protruding portion CP3 may protrude in the third direction Z from an upper surface of the third extension portion EP3. The upper surface of the third extension portion EP3 may define a lower surface of a third recess 220r3, and a side surface of the third protruding portion CP3 may define a side surface of the third recess 220r3.

In some example embodiments, a filling insulating film 220 may be formed to fill the recesses 220r1 to 220r5 of the source/drain contacts CA11 to CA22. The filling insulating film 220 may form an insulating region within the source/drain contacts CA11 to CA22. The filling insulating film 220 may include, but is not limited to, for example, at least one of silicon oxide (SiO), silicon oxynitride (SiON), silicon oxycarbonitride (SiOCN), or a combination thereof.

In some example embodiments, each of the source/drain contacts CA11 to CA22 may include a first barrier conductive film 211 and a first filling conductive film 212. The first barrier conductive film 211 may be interposed between the interlayer insulating films 110 and 210 and the first filling conductive film 212. The first barrier conductive film 211 may include metal or metal nitride to prevent diffusion of the first filling conductive film 212. For example, the first barrier conductive film 211 may include, but is not limited to, at least one of titanium (Ti), tantalum (Ta), tungsten (W), nickel (Ni), cobalt (Co), platinum (Pt), an alloy thereof, and nitrides thereof.

The first filling conductive film 212 may fill a space remaining after the first barrier conductive film 211 is formed. The first filling conductive film 212 may include, but is not limited to, for example, at least one of aluminum (Al), copper (Cu), tungsten (W), molybdenum (Mo), cobalt (Co), and an alloy thereof.

The etch stop layer 310 may be formed on the source/drain contacts CA11 to CA22 and the interlayer insulating films 110 and 210. For example, the etch stop layer 310 may cover the upper surfaces of the source/drain contacts CA11 to CA22 and the upper surface of the second interlayer insulating film 210.

A third interlayer insulating film 320 may be formed on the etch stop layer 310. The third interlayer insulating film 320 may include, but is not limited to, for example, at least one of silicon oxide, silicon oxynitride, and a low-k material having a dielectric constant lower than that of silicon oxide. The etch stop layer 310 may have an etch selectivity different from that of the third interlayer insulating film 320. As an example, when the third interlayer insulating film 320 includes silicon oxide, the etch stop layer 310 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and a combination thereof. The etch stop layer 310 may be provided as an etch stop layer in an etching process for the third interlayer insulating film 320.

The gate contact VB may be formed on gate structures G1 to G3. The gate contact VB may be electrically connected to at least some of the gate structures G1 to G3. For example, as illustrated in FIG. 3, the gate contact VB may penetrate through the third interlayer insulating film 320, the etch stop layer 310, the second interlayer insulating film 210, and the gate capping pattern 150 and be connected to the gate electrode 130.

Via patterns VA11 to VA13 may be formed on source/drain contacts CA11 to CA22. The via patterns VA11 to VA13 may penetrate through the third interlayer insulating film 320 and the etch stop layer 310 and be electrically connected to the source/drain contacts CA11 to CA22. For example, a first via pattern VA11 may be connected to the upper surface of the first source/drain contact CA11, a second via pattern VA12 may be connected to the upper surface of the second source/drain contact CA12, and a third via pattern VA13 may be connected to the upper surface of the third source/drain contact CA13.

In some example embodiments, the via patterns VA11 to VA13 may be connected to regions of the source/drain contacts CA11 to CA22 where the recesses 220r1 to 220r5 are not formed. For example, the first via pattern VA11 may be in contact with the upper surface of the first protruding portion CP1, the second via pattern VA12 may be in contact with the upper surface of the second protruding portion CP2, and the third via pattern VA13 may be in contact with the upper surface of the third protruding portion CP3. In some example embodiments, the via patterns VA11 to VA13 may not overlap the recesses 220r1 to 220r5 in the third direction Z.

In some example embodiments, the gate contact VB may include a second barrier conductive film 325 and a second filling conductive film 326, and each of the via patterns VA11 to VA13 may include a third barrier conductive film 321 and a third filling conductive film 322.

The second barrier conductive film 325 may be interposed between the interlayer insulating films 110 and 210, the etch stop layer 310, and the third interlayer insulating film 320 and the second filling conductive film 326. The second barrier conductive film 325 may include metal or metal nitride to prevent diffusion of the second filling conductive film 326. The third barrier conductive film 321 may be interposed between the etch stop layer 310 and the third interlayer insulating film 320, and the third filling conductive film 322. The third barrier conductive film 321 may include metal or metal nitride to prevent diffusion of the third filling conductive film 322. For example, each of the second barrier conductive film 325 and the third barrier conductive film 321 may include, but is not limited to, at least one of titanium (Ti), tantalum (Ta), tungsten (W), nickel (Ni), cobalt (Co), platinum (Pt), an alloy thereof, and nitrides thereof.

The second filling conductive film 326 may fill a space remaining after the second barrier conductive film 325 is formed. The third filling conductive film 322 may fill a space remaining after the third barrier conductive film 321 is formed. Each of the second filling conductive film 326 and the third filling conductive film 322 may include, but is not limited to, for example, at least one of aluminum (Al), copper (Cu), tungsten (W), molybdenum (Mo), cobalt (Co), and an alloy thereof.

In some example embodiments, the gate contact VB and via patterns VA11 to VA13 may be formed at the same level. Herein, the term “same level” refers to formation by the same fabricating process.

Rail patterns VR1 and VR2 may be formed in the etch stop layer 310 and/or the third interlayer insulating film 320. The rail patterns VR1 and VR2 may be spaced apart from each other and extend parallel to each other in the first direction X. In some example embodiments, a first rail pattern VR1 may be disposed on one side of the first cell region CR1 (e.g., between the first cell region CR1 and the second cell region CR2), and the second rail pattern VR2 may be disposed on the other side of the first cell region CR1.

The rail patterns VR1 and VR2 may be connected to side surfaces of at least some of the via patterns VA11 to VA13. For example, the first rail pattern VR1 may be connected to a side surface of the second via pattern VA12, and the second rail pattern VR2 may be connected to a side surface of the third via pattern VA13. In some example embodiments, the first via pattern VA11 may be spaced apart from the first rail pattern VR1 and the second rail pattern VR2 in the second direction Y. For example, the first via pattern VA11 may be disposed between the first rail pattern VR1 and the second rail pattern VR2.

In some example embodiments, the rail patterns VR1 and VR2 may be formed on the etch stop layer 310. Lower surfaces of the rail patterns VR1 and VR2 may be formed to be higher than the upper surfaces of the source/drain contacts CA11 to CA22 and/or the lower surfaces of the via patterns VA11 to VA13. For example, as illustrated in FIGS. 6 and 7, a lower surface of the first rail pattern VR1 may be spaced apart from the upper surface of the second source/drain contact CA12.

In some example embodiments, the upper surfaces of the rail patterns VR1 and VR2 may be disposed on the same plane (i.e., coplanar surface) with the upper surfaces of the via patterns VA11 to VA13. For example, the upper surfaces of the rail patterns VR1 and VR2 and the upper surfaces of the via patterns VA11 to VA13 may both be disposed on the coplanar surface with the upper surface of the third interlayer insulating film 320. In the present specification, the term “same” refers to the meaning including not only the completely same, but also a fine difference that may occur due to a margin in a process or the like.

In some example embodiments, a height of the rail patterns VR1 and VR2 may be smaller than a height of the via patterns VA11 to VA13. For example, in the third direction Z, the height of the via patterns VA11 to VA13 (e.g., H1 in FIG. 6) may be about 20 nm to about 50 nm, and the height of the rail patterns VR1 and VR2 may be smaller than the height of the via patterns VA11 to VA13.

In some example embodiments, the recesses (e.g., the first, fourth, and fifth recesses 220r1, 220r4, and 220r5) of the source/drain contacts (e.g., the first, fourth, and fifth source/drain contacts CA11, CA21, and CA22) among the source/drain contacts CA11 to CA22 that are not connected to the rail patterns VR1 and VR2 may be formed adjacent to the rail patterns VR1 and VR2. For example, as illustrated in FIGS. 4 and 5, a portion of the first recess 220r1 may be disposed between the first via pattern VA11 and the first rail pattern VR1, and another portion of the first recess 220r1 may be disposed between the first via pattern VA11 and the second rail pattern VR2. At least a portion of the fourth recess 220r4 may be adjacent to the first rail pattern VR1. In addition, for example, as illustrated in FIGS. 6 and 7, at least a portion of the fifth recess 220r5 may be adjacent to the first rail pattern VR1.

In some example embodiments, each of the rail patterns VR1 and VR2 may include a fourth barrier conductive film 323 and a fourth filling conductive film 324. The fourth barrier conductive film 323 may be interposed between the etch stop layer 310 and the third interlayer insulating film 320, and the fourth filling conductive film 324. The fourth barrier conductive film 323 may include metal or metal nitride to prevent diffusion of the fourth filling conductive film 324. For example, the fourth barrier conductive film 323 may include, but is not limited to, at least one of titanium (Ti), tantalum (Ta), tungsten (W), nickel (Ni), cobalt (Co), platinum (Pt), an alloy thereof, and nitrides thereof. The fourth filling conductive film 324 may fill a space remaining after the fourth barrier conductive film 323 is formed. The fourth filling conductive film 324 may include, but is not limited to, for example, at least one of aluminum (Al), copper (Cu), tungsten (W), molybdenum (Mo), cobalt (Co), and an alloy thereof.

In some example embodiments, at least some of the via patterns VA11 to VA13 may include a via trench 320r, and some of the rail patterns VR1 and VR2 may fill the via trench 320r. For example, as illustrated in FIG. 7, the second via pattern VA12 may include the via trench 320r. The via trench 320r may overlap a portion of the first rail pattern VR1 in the third direction Z. A portion of the first rail pattern VR1 may fill the via trench 320r. As an example, in the etching process for forming the first rail pattern VR1, a portion of the second via pattern VA12 that overlaps the first rail pattern VR1 in the third direction Z may be completely removed. In this case, the second via pattern VA12 may be connected to a lower surface of the first rail pattern VR1 and a side surface of the first rail pattern VR1.

The inter-wiring insulating film 330 may be formed on the third interlayer insulating film 320, the via patterns VA11 to VA13, and the rail patterns VR1 and VR2. For example, the inter-wiring insulating film 330 may cover an upper surface of the third interlayer insulating film 320, upper surfaces of the via patterns VA11 to VA13, and upper surfaces of the rail patterns VR1 and VR2. The inter-wiring insulating film 330 may include, but is not limited to, for example, at least one of silicon oxide, silicon oxynitride, and a low-k material having a dielectric constant lower than that of silicon oxide.

The wiring patterns PW1, PW2, RW1, and RW2 may be formed in the inter-wiring insulating film 330. The wiring patterns PW1, PW2, RW1, and RW2 may penetrate through the inter-wiring insulating film 330 and be electrically connected to the via patterns VA11 to VA13 and/or the rail patterns VR1 and VR2. The wiring patterns PW1, PW2, RW1, and RW2 may include a first power wiring PW1 and a second power wiring PW2. The first power wiring PW1 and the second power wiring PW2 may be spaced apart from each other and extend parallel to each other in the first direction X. In some example embodiments, the first power wiring PW1 may be disposed on one side of the first cell region CR1 (e.g., between the first cell region CR1 and the second cell region CR2), and the second power wiring PW2 may be disposed on the other side of the first cell region CR1.

The first power wiring PW1 may be connected to the upper surface of the first rail pattern VR1. The first power wiring PW1 may provide a first power voltage to the first cell region CR1 and/or the second cell region CR2. For example, the first power wiring PW1 may provide the first power voltage to the second source/drain contact CA12 through the first rail pattern VR1 and the second via pattern VA12. The first power voltage may be, but is not limited to, for example, a drain voltage V_{DD} having a positive (+) voltage.

The second power wiring PW2 may be connected to the upper surface of the second rail pattern VR2. The second power wiring PW2 may provide a second power voltage different from the first power voltage to the first cell region CR1 and/or the second cell region CR2. For example, the second power wiring PW2 may provide the second power voltage to the third source/drain contact CA13 through the second rail pattern VR2 and the third via pattern VA13. The second power voltage may be, but is not limited to, for example, a source voltage V_{SS} having a negative (−) voltage or a ground voltage.

In some example embodiments, a width of each of the rail patterns VR1 and VR2 may be smaller than a width of each of the power wirings PW1 and PW2. For example, as illustrated in FIG. 5, based on the upper surface of the third interlayer insulating film 320, a width W1 of the first rail pattern VR1 in the second direction Y may be smaller than a width W2 of the first power wiring PW1 in the second direction Y. In this case, as illustrated in FIG. 7, the first power wiring PW1 may be connected to both the upper surface of the first rail pattern VR1 and the upper surface of the second via pattern VA12. However, the teachings of the present inventive concept are not limited thereto, and the width of each of the rail patterns VR1 and VR2 may be equal to or greater than the width of each of the power wirings PW1 and PW2.

In some example embodiments, the wiring patterns PW1, PW2, RW1, and RW2 may further include a first routing wiring RW1 and a second routing wiring RW2. The first routing wiring RW1 and the second routing wiring RW2 may be spaced apart from each other and extend parallel to each other in the first direction X. The first routing wiring RW1 and the second routing wiring RW2 may be disposed in the first cell region CR1. For example, the first routing wiring RW1 and the second routing wiring RW2 may be disposed between the first power wiring PW1 and the second power wiring PW2.

The first routing wiring RW1 and the second routing wiring RW2 may be electrically connected to at least a portion of the via patterns VA11 to VA13 and the gate contact VB, respectively. As an example, the first routing wiring RW1 may be connected to the upper surface of the first via pattern VA11, and the second routing wiring RW2 may be connected to the upper surface of the gate contact VB.

As semiconductor devices become more highly integrated, the width of wiring patterns and via patterns that implement the semiconductor devices is gradually decreasing. For this reason, a voltage drop (e.g., IR drop) of a power delivery network PDN that supplies a power voltage to electronic devices has emerged as an important problem.

The semiconductor device according to some example embodiments may reduce the voltage drop caused by the power wirings PW1 and PW2 by using the rail patterns VR1 and VR2 connected to the power wirings PW1 and PW2. Specifically, as described above, the power wirings PW1 and PW2 may extend in the first direction X, and the rail patterns VR1 and VR2 may extend in the first direction X under the power wirings PW1 and PW2. The rail patterns VR1 and VR2 may be disposed to overlap the power wirings PW1 and PW2 in the third direction Z, thereby reducing electrical resistance caused by the power wirings PW1 and PW2. For example, the first rail pattern VR1 may reduce electrical resistance in a horizontal direction (e.g., the first direction X) by providing an additional cross-sectional area in addition to a cross-sectional area of the first power wiring PW1 in an electrical path that provides the power voltage. In addition, for example, as illustrated in FIGS. 6 and 7, the first rail pattern VR1 may reduce electrical resistance in a vertical direction (e.g., the third direction Z) by providing an additional contact area with the first power wiring PW1 in addition to a contact area between the first power wiring PW1 and the second via pattern VA12. Through this, a semiconductor device with improved performance may be provided.

In addition, the semiconductor device according to some example embodiments may prevent a short circuit between the rail patterns VR1 and VR2 and the source/drain contacts CA11 to CA22 by using the source/drain contacts CA11 to CA22 including the recesses 220r1 to 220r5. For example, as illustrated in FIG. 5, as the first source/drain contact CA11 includes the first recess 220r1 adjacent to the first rail pattern VR1, the first source/drain contact CA11 may be spaced apart from the first rail pattern VR1 by D1. If the first source/drain contact CA11 does not include the first recess 220r1 (e.g., if the first barrier conductive film 211 and/or the first filling conductive film 212 replace the area where the filling insulating film 220 is formed), a short circuit between the first rail pattern VR1 and the first source/drain contact CA11 may be a problem because a distance D2 between the first source/drain contact CA11 and the first rail pattern VR1 is narrow. That is, the source/drain contacts CA11 to CA22 including the recesses 220r1 to 220r5 may also provide a space for disposing the rail patterns VR1 and VR2 and may also provide a space for the rail patterns VR1 and VR2 having a wider width. Through this, a semiconductor device with further improved performance may be provided.

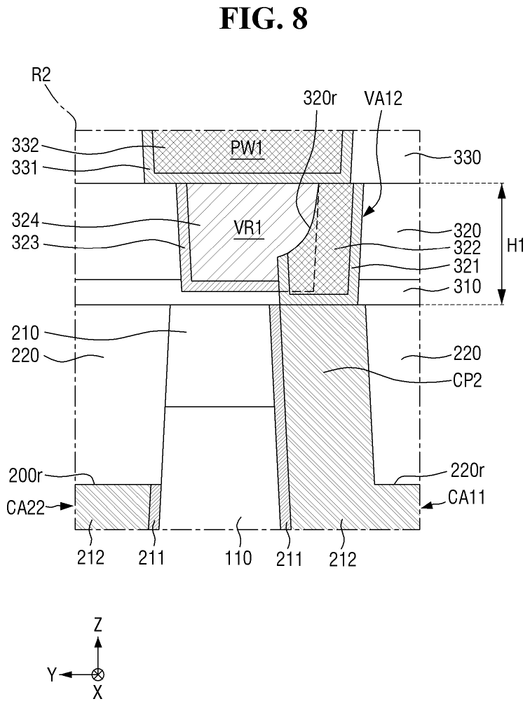

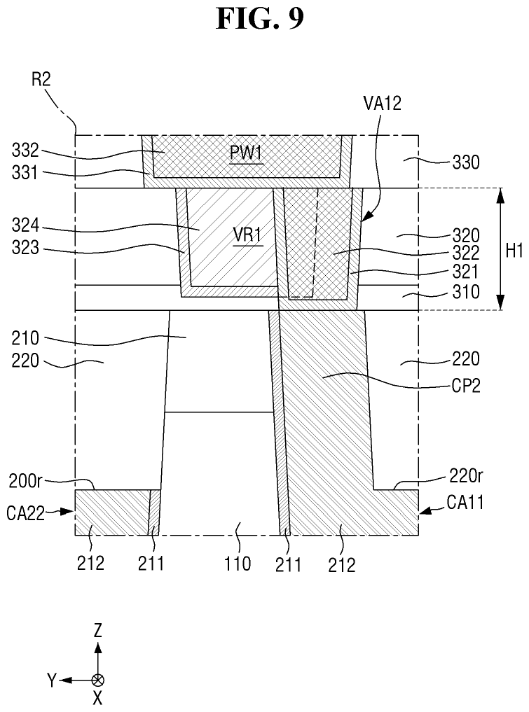

FIGS. 8 and 9 are other various enlarged views for describing the R2 region of FIG. 6. For convenience of explanation, portions overlapping those described above with reference to FIGS. 1 to 7 will be briefly described or omitted. Referring to FIGS. 8 and 9, in the semiconductor device according to some example embodiments, a portion of the second via pattern VA12 overlaps the first rail pattern VR1 in the first direction X.

For example, as illustrated in FIG. 8, a lowermost surface of the via trench 320r may be formed to be higher than the lower surface of the first rail pattern VR1. As an example, in the etching process for forming the first rail pattern VR1, a portion of the second via pattern VA12 that overlaps the first rail pattern VR1 in the third direction Z may not be completely removed.

Alternatively, for example, as illustrated in FIG. 9, the via trench 320r may not be formed in the second via pattern VA12. As an example, in the etching process for forming the first rail pattern VR1, the second via pattern VA12 may not be etched. In this case, the second via pattern VA12 may be connected only to the side surface of the first rail pattern VR1 and may not be connected to the lower surface of the first rail pattern VR1.

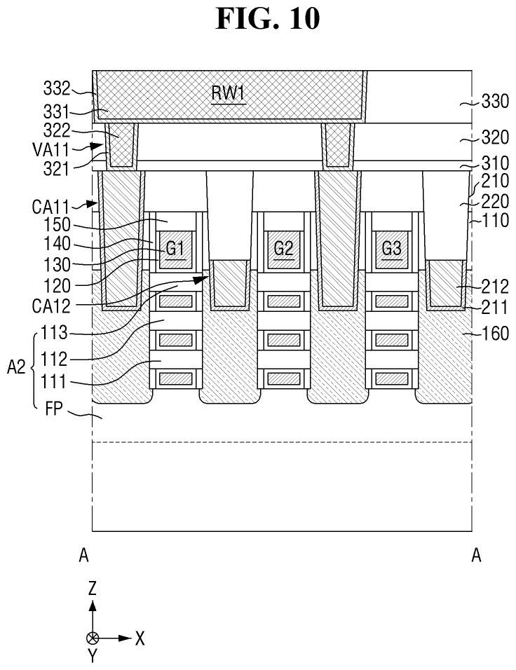

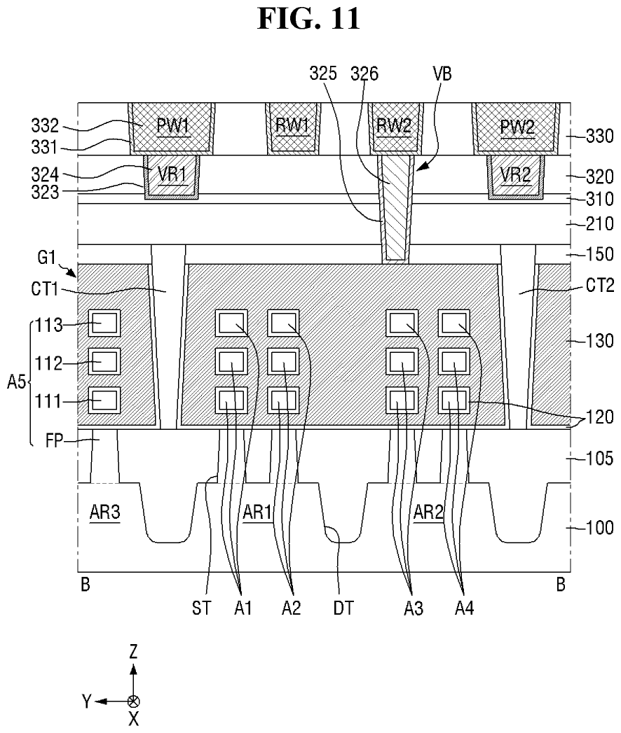

FIG. 10 is another cross-sectional view taken along line A-A of FIG. 1. FIG. 11 is another cross-sectional view taken along line B-B of FIG. 1. For convenience of explanation, portions overlapping those described above with reference to FIGS. 1 to 9 will be briefly described or omitted. Referring to FIGS. 1, 10, and 11, in the semiconductor device according to some example embodiments, each of the active patterns A1 to A5 includes a plurality of bridge patterns 111, 112, and 113.

For example, each of the active patterns A1 to A5 may include a first bridge pattern 111, a second bridge pattern 112, and a third bridge pattern 113 that are sequentially stacked on the upper surface of the substrate 100 and spaced apart from each other. The first bridge pattern 111 may be spaced apart from the substrate 100 in the third direction Z, the second bridge pattern 112 may be spaced apart from the first bridge pattern 111 in the third direction Z, and the third bridge pattern 113 may be spaced apart from the second bridge pattern 112 in the third direction Z.

The bridge patterns 111, 112, and 113 may each extend in the first direction X. In addition, the bridge patterns 111, 112, and 113 may respectively penetrate through the gate structures G1 to G3. That is, the gate structures G1 to G3 may have a shape surrounding an outer peripheral surface of each of the bridge patterns 111, 112, and 113. The bridge patterns 111, 112, and 113 may be used as a channel region of an MBCFET® including a multi-bridge channel. The number of bridge patterns included in the active pattern AP is only an example, and is not limited to that illustrated.

In FIG. 11, a cross-section of each of the bridge patterns 111, 112, and 113 is illustrated to be rectangular, but this is only an example, and the cross-section of each of the bridge patterns 111, 112, and 113 may have various shapes, such as polygonal, circular, or oval shapes.

In some example embodiments, each of the active patterns A1 to A5 may include a fin-shaped pattern FP that protrudes from an upper surface of the substrate 100 and extends in the first direction X. For example, the first bridge pattern 111 may be spaced apart from the fin-shaped pattern FP in the third direction Z.

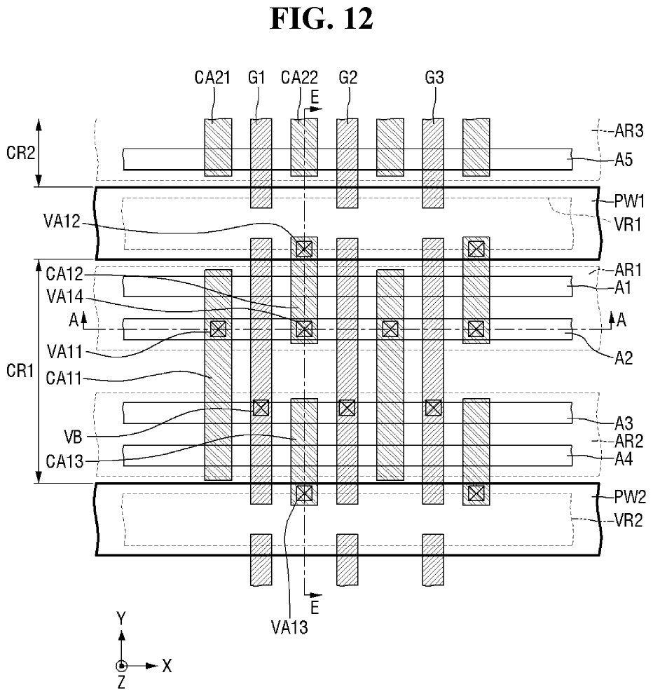

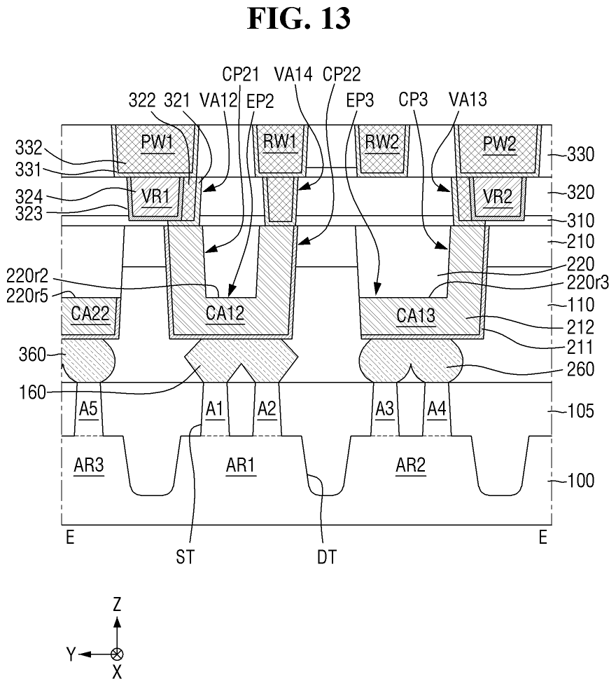

FIG. 12 is a schematic layout view for describing a semiconductor device according to some example embodiments. FIG. 13 is a cross-sectional view taken along line E-E of FIG. 12. For convenience of explanation, portions overlapping those described above with reference to FIGS. 1 to 11 will be briefly described or omitted. Referring to FIGS. 12 and 13, the semiconductor device according to some example embodiments further includes a fourth via pattern VA14.

The fourth via pattern VA14 may connect the second source/drain contact CA12 and the first routing wiring RW1. For example, the fourth via pattern VA14 may be connected to an upper surface of the second source/drain contact CA12, and the first routing wiring RW1 may be connected to an upper surface of the fourth via pattern VA14. The first power wiring PW1 may be electrically connected to the first routing wiring RW1 through the first rail pattern VR1, the second via pattern VA12, the second source/drain contact CA12, and the fourth via pattern VA14.

In some example embodiments, the second source/drain contact CA12 may include a fourth protruding portion CP21 and a fifth protruding portion CP22 that respectively protrude from the upper surface of the second extension portion EP2 in the third direction Z. The second via pattern VA12 may contact an upper surface of the fourth protruding portion CP21, and the fourth via pattern VA14 may contact an upper surface of the fifth protruding portion CP22. The second recess 220r2 may be defined between the fourth protruding portion CP21 and the fifth protruding portion CP22.

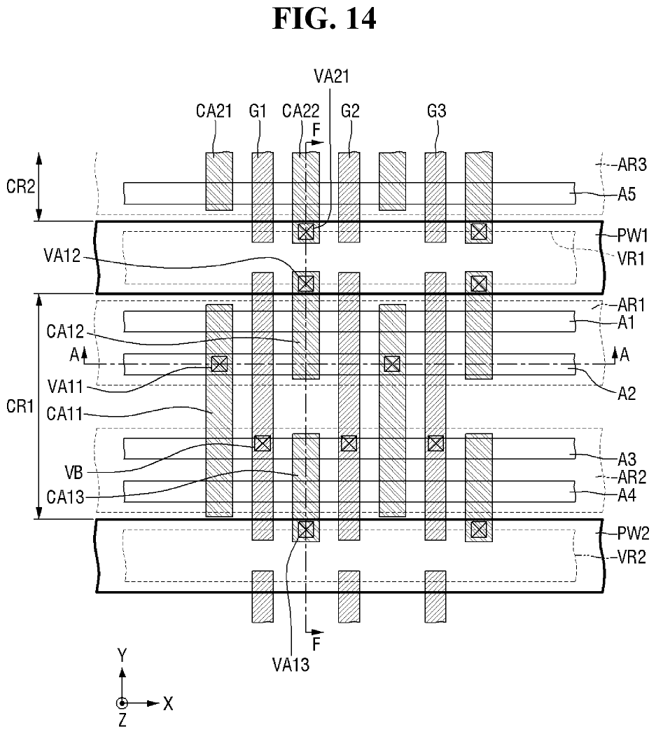

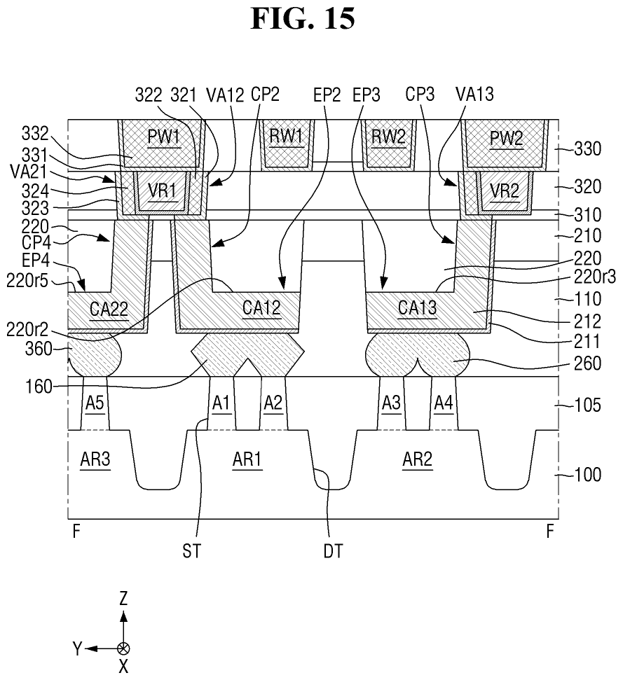

FIG. 14 is a schematic layout view for describing a semiconductor device according to some example embodiments. FIG. 15 is a cross-sectional view taken along line F-F of FIG. 14. For convenience of explanation, portions overlapping those described above with reference to FIGS. 1 to 11 will be briefly described or omitted. Referring to FIGS. 14 and 15, the semiconductor device according to some example embodiments further includes a fifth via pattern VA21.

The fifth via pattern VA21 may connect the fifth source/drain contact CA22 and the first rail pattern VR1. For example, the fifth via pattern VA21 may be connected to an upper surface of the fifth source/drain contact CA22, and the first rail pattern VR1 may be connected to a side surface of the fifth via pattern VA21. The first power wiring PW1 may be connected to the upper surface of the first rail pattern VR1, the second via pattern VA12, and/or the fifth via pattern VA21. The first power wiring PW1 may provide the first power voltage to the second source/drain contact CA12 and the fifth source/drain contact CA22 through the first rail pattern VR1, the second via pattern VA12, and the fifth via pattern VA21.

In some example embodiments, the fifth source/drain contact CA22 may include a fourth extension portion EP4 and a sixth protruding portion CP4 protruding from an upper surface of the fourth extension portion EP4 in the third direction Z. The fifth via pattern VA21 may be in contact with an upper surface of the sixth protruding portion CP4. The upper surface of the fourth extension portion EP4 may define a lower surface of the fifth recess 220r5, and a side surface of the sixth protruding portion CP4 may define a side surface of the fifth recess 220r5.

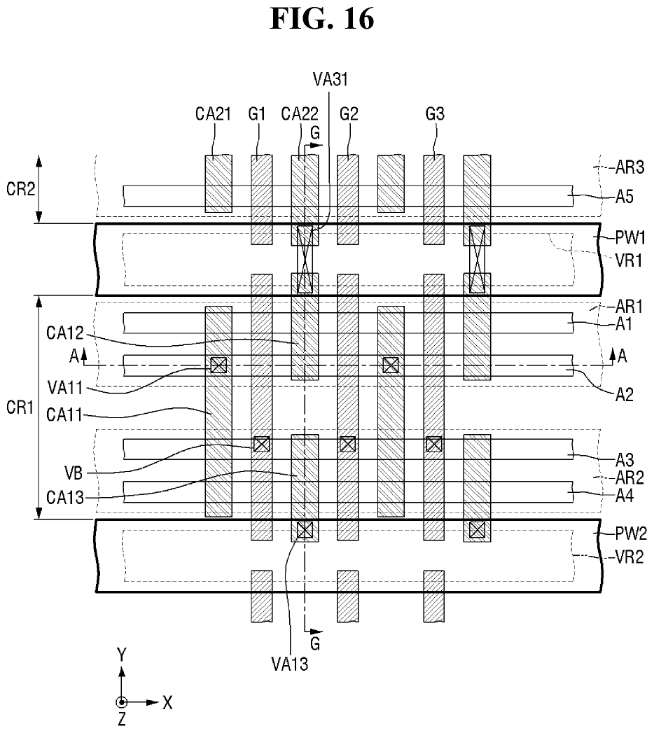

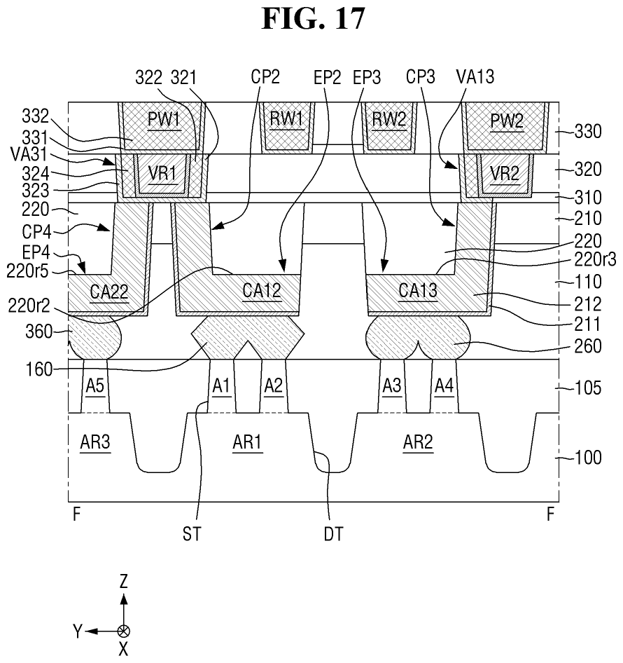

FIG. 16 is a schematic layout view for describing a semiconductor device according to some example embodiments. FIG. 17 is a cross-sectional view taken along line G-G of FIG. 16. For convenience of explanation, portions overlapping those described above with reference to FIGS. 1 to 11 will be briefly described or omitted. Referring to FIGS. 16 and 17, the semiconductor device according to some example embodiments further includes a sixth via pattern VA31.

The sixth via pattern VA31 may connect the second source/drain contact CA12 and the first rail pattern VR1, and may connect the fifth source/drain contact CA22 and the first rail pattern VR1. For example, the sixth via pattern VA31 may extend in the second direction Y and be connected to the upper surface of the second source/drain contact CA12 and the upper surface of the fifth source/drain contact CA22. In addition, the sixth via pattern VA31 may be connected to the side surface of the first rail pattern VR1. The first power wiring PW1 may be connected to the upper surface of the first rail pattern VR1 and/or the sixth via pattern VA31. The first power wiring PW1 may provide the first power voltage to the second source/drain contact CA12 and the fifth source/drain contact CA22 through the first rail pattern VR1 and the sixth via pattern VA31.

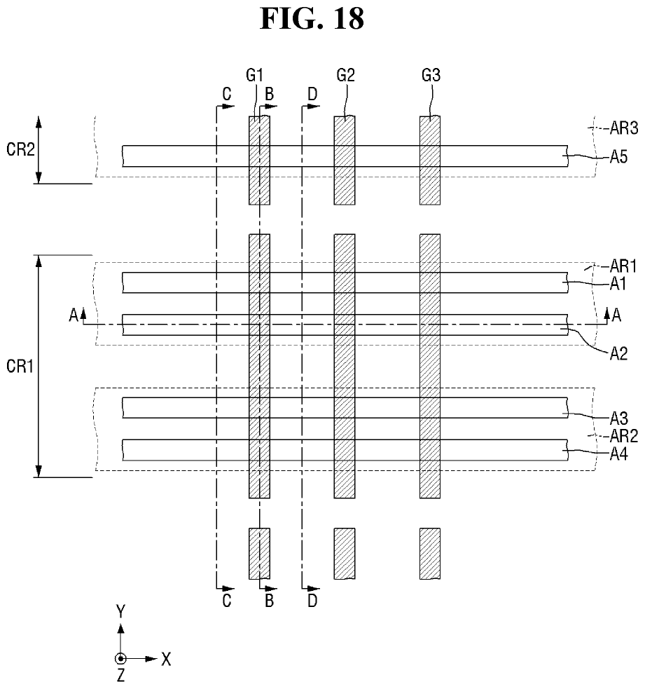

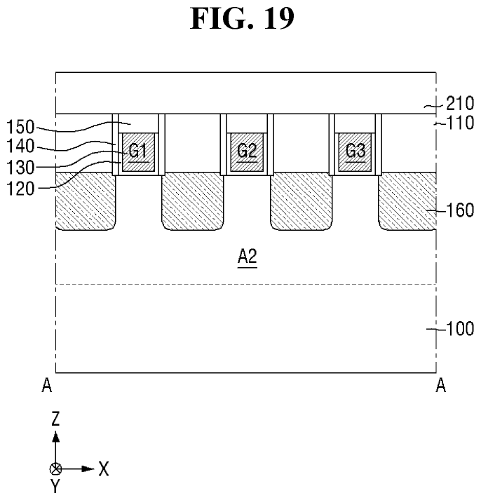

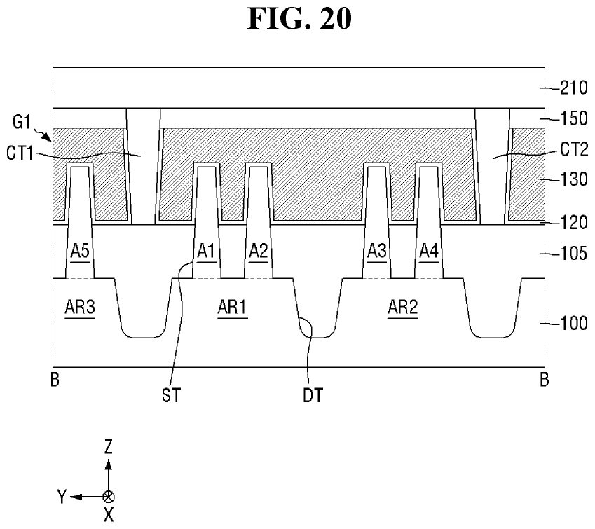

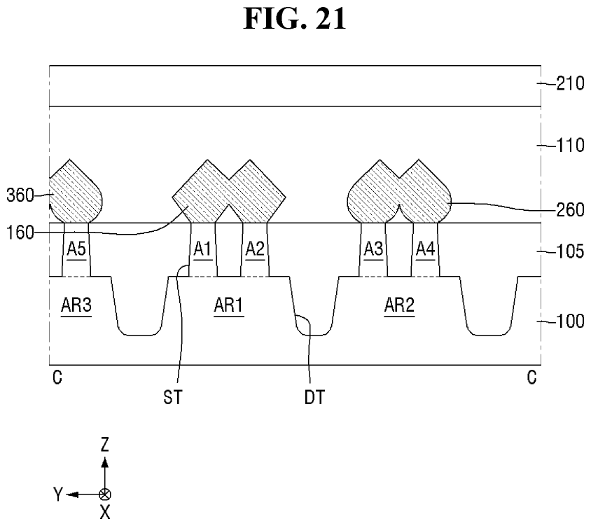

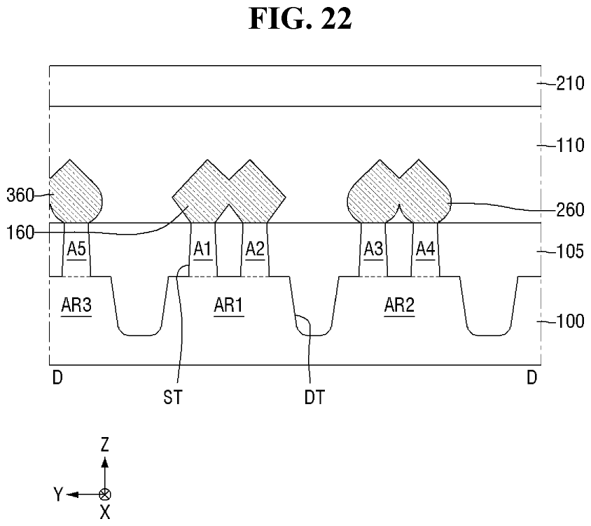

Hereinafter, a method for fabricating a semiconductor device according to example embodiments will be described with reference to FIGS. 1 to 29. FIGS. 18 to 29 are intermediate step views for describing a method for fabricating a semiconductor device according to some example embodiments. For convenience of explanation, portions overlapping those described above with reference to FIGS. 1 to 17 will be briefly described or omitted. Referring to FIGS. 18 to 22, active patterns A1 to A5 and gate structures G1 to G3 are formed on a substrate 100. For reference, FIG. 19 is a cross-sectional view taken along line A-A of FIG. 18, FIG. 20 is a cross-sectional view taken along line B-B of FIG. 18, FIG. 21 is a cross-sectional view taken along line C-C of FIG. 18, and FIG. 22 is a cross-sectional view taken along line D-D of FIG. 18.

For example, a substrate 100 including a first cell region CR1 and a second cell region CR2 may be provided. Subsequently, a first trench DT defining a first active region AR1, a second active region AR2, and a third active region AR3 may be formed in the substrate 100. Subsequently, a second trench ST defining the active patterns A1 to A5 may be formed on the active regions AR1 to AR3. Subsequently, a field insulating film 105 may be formed on the substrate 100. The field insulating film 105 may be formed to surround at least a portion of side surfaces of the active patterns A1 to A5.

Subsequently, gate structures G1 to G3 may be formed on the active patterns A1 to A5 and the field insulating film 105. Each of the gate structures G1 to G3 may include a gate electrode 130, a gate insulating film 120, a gate spacer 140, and a gate capping pattern 150. The gate electrode 130 may be formed through, for example, a replacement process, but is not limited thereto. Subsequently, source/drain regions 160, 260, and 360 may be formed on the active patterns A1 to A5. In some example embodiments, the source/drain regions 160, 260, and 360 may include epitaxial layers formed in the active patterns A1 to A5 on both sides of the gate structures G1 to G3. Subsequently, a first interlayer insulating film 110 and a second interlayer insulating film 210 covering the field insulating film 105, the source/drain regions 160, 260, and 360, and the gate structures G1 to G3 may be formed.

In some example embodiments, a first gate cutting pattern CT1 and a second gate cutting pattern CT2 for cutting the gate structures G1 to G3 may be formed. The first gate cutting pattern CT1 and the second gate cutting pattern CT2 may be formed, for example, before the replacement process is performed, but are not limited thereto.

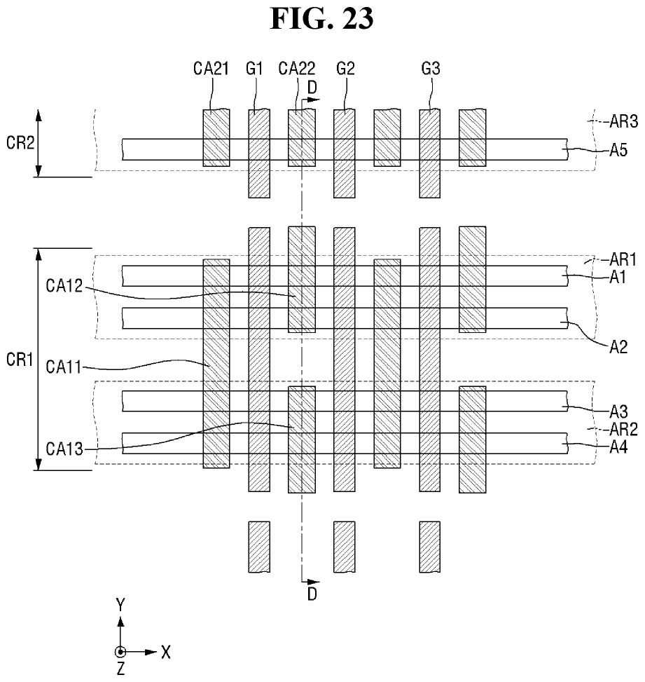

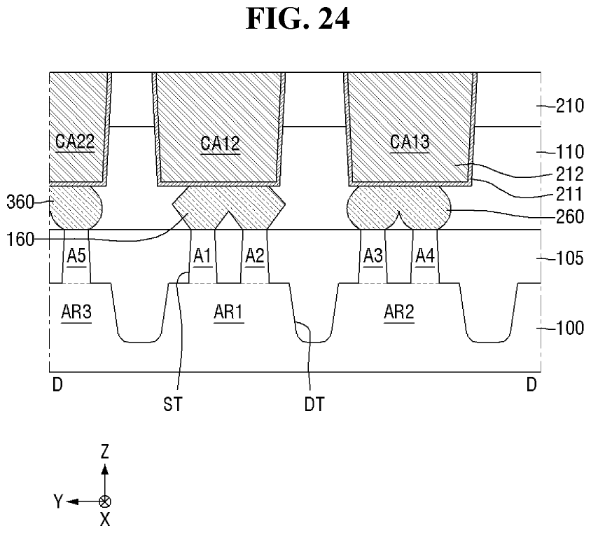

Referring to FIGS. 23 and 24, source/drain contacts CA11 to CA22 are formed. For reference, FIG. 24 is a cross-sectional view taken along line D-D of FIG. 23. The source/drain contacts CA11 to CA22 may be disposed on the side surfaces of the gate structures G1 to G3. The source/drain contacts CA11 to CA22 may penetrate through the first interlayer insulating film 110 and the second interlayer insulating film 210 and be connected to the source/drain regions 160, 260, and 360.

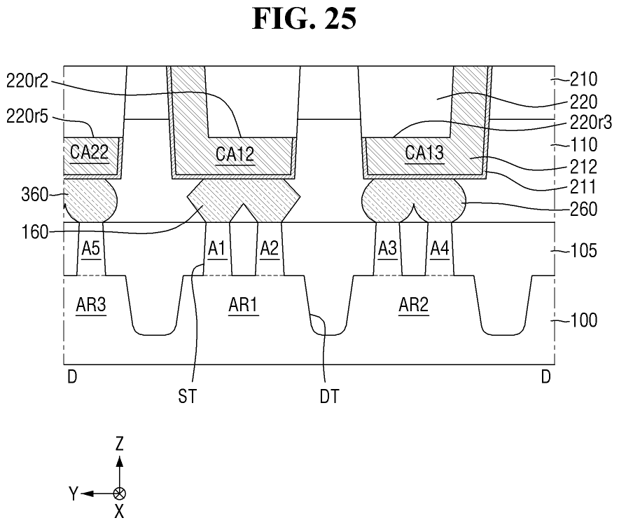

Referring to FIG. 25, recesses 220r1 to 220r5 are formed in the source/drain contacts CA11 to CA22. For example, a recess process may be performed on a portion of each of the source/drain contacts CA11 to CA22 to form the source/drain contacts CA11 to CA22 including the recesses 220r1 to 220r5. Subsequently, a filling insulating film 220 filling the recesses 220r1 to 220r5 may be formed.

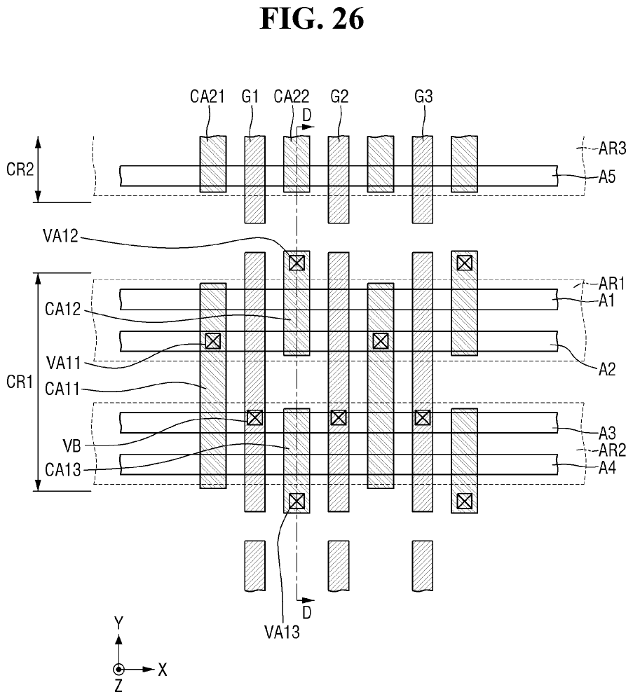

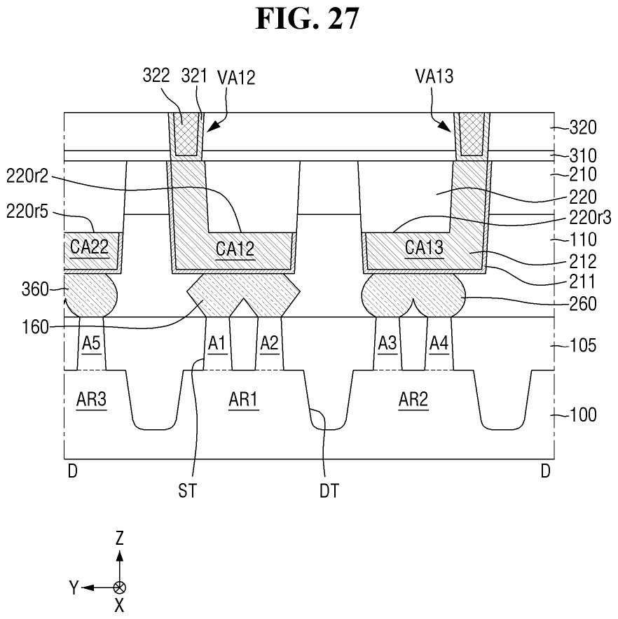

Referring to FIGS. 26 and 27, a gate contact VB and via patterns VA11 to VA13 are formed. For reference, FIG. 27 is a cross-sectional view taken along line D-D of FIG. 26. For example, an etch stop layer 310 and a third interlayer insulating film 320 may be sequentially stacked on the source/drain contacts CA11 to CA22 and the interlayer insulating films 110 and 210. The gate contact VB may penetrate through the third interlayer insulating film 320, the etch stop layer 310, the second interlayer insulating film 210, and the gate capping pattern 150 and be connected to the gate electrode 130. The via patterns VA11 to VA13 may penetrate through the third interlayer insulating film 320 and the etch stop layer 310 and be electrically connected to the source/drain contacts CA11 to CA22.

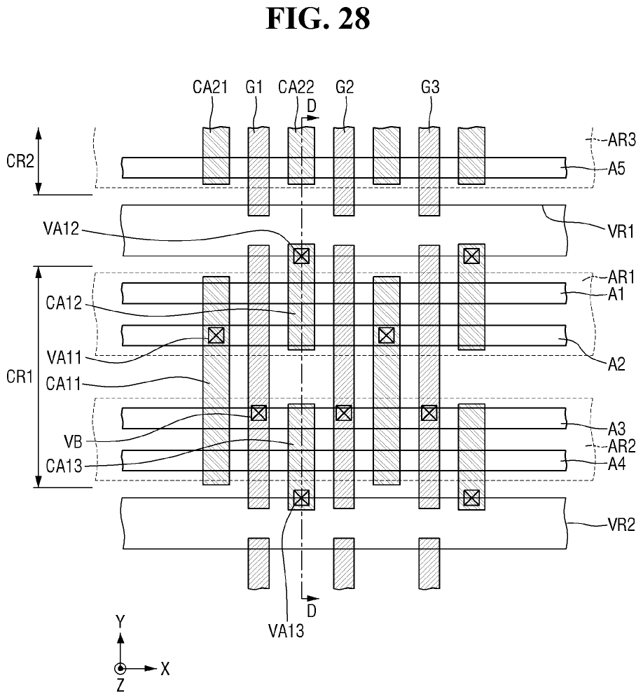

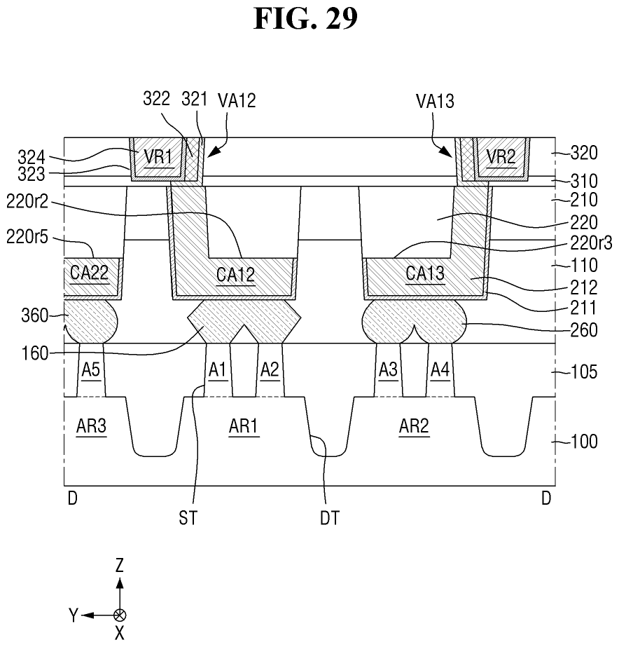

Referring to FIGS. 28 and 29, rail patterns VR1 and VR2 are formed. For reference, FIG. 29 is a cross-sectional view taken along line D-D of FIG. 28. For example, an etching process of using the etch stop layer 310 as an etch stop layer may be performed. Subsequently, a fourth barrier conductive film 323 and a fourth filling conductive film 324 that fill the region etched by the etching process may be formed. In some example embodiments, the etching process may also be performed on a portion of the second via pattern VA12 and a portion of the third via pattern VA13. Through this, a first rail pattern VR1 connected to a side surface of the second via pattern VA12 and a second rail pattern VR2 connected to a side surface of the third via pattern VA13 may be formed.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor device, comprising:
an active pattern extending in a first direction across an underlying substrate;
a gate structure extending in a second direction, on the active pattern;
a first source/drain contact electrically connected to a source/drain region within the active pattern, on one side of the gate structure;
a first via pattern electrically connected to an upper surface of the first source/drain contact;
a rail pattern extending in the first direction, and spaced apart from the first via pattern in the second direction; and
a wiring pattern extending in the first direction, and electrically connected to an upper surface of the rail pattern;
wherein the first source/drain contact includes a first recess therein, which is more recessed downwardly relative to the upper surface of the first source/drain contact; and
wherein at least a portion of the first recess extends adjacent to the rail pattern.

2. The device of claim 1, wherein the first and second directions are orthogonal to each other; wherein the first source/drain contact includes an extension portion extending in the second direction, and a protruding portion protruding upwardly from an upper surface of the extension portion; wherein the upper surface of the extension portion defines a lower surface of the first recess; and wherein a side surface of the protruding portion defines a side surface of the first recess.

3. The device of claim 2, wherein the first via pattern is in contact with an upper surface of the protruding portion.

4. The device of claim 1, further comprising a filling insulating film, which fills the first recess.

5. The device of claim 1, wherein an upper surface of the first via pattern and the upper surface of the rail pattern are coplanar.

6. The device of claim 1, further comprising:
a first interlayer insulating film covering the active pattern and the gate structure, on the substrate; and
an etch stop layer covering an upper surface of the first interlayer insulating film and the upper surface of the first source/drain contact;
wherein the first via pattern penetrates through the etch stop layer and is electrically connected to the upper surface of the first source/drain contact; and
wherein the rail pattern extends on the etch stop layer.

7. The device of claim 1, further comprising:
a second source/drain contact electrically connected to a source/drain region of the active pattern on the other side of the gate structure; and
a second via pattern electrically connected to an upper surface of the second source/drain contact; and
wherein the second via pattern is connected to a side surface of the rail pattern.

8. The device of claim 7, wherein the second source/drain contact includes a second recess recessed more downwardly than the upper surface of the second source/drain contact.

9. A semiconductor device, comprising:
a first active pattern extending in a first direction across an underlying substrate;
a gate structure extending in a second direction intersecting the first direction, on the first active pattern;
a first source/drain contact electrically connected to a first source/drain region of the first active pattern, on one side of the gate structure;
a first via pattern electrically connected to an upper surface of the first source/drain contact;
a rail pattern extending in the first direction, and electrically connected to a side surface of the first pattern; and
a wiring pattern extending in the first direction, and electrically connected to an upper surface of the rail pattern; and
wherein the first source/drain contact includes a first recess, which is recessed more downwardly than the upper surface of the first source/drain contact.

10. The device of claim 9,
wherein the first source/drain contact includes an extension portion extending in the second direction, and a protruding portion protruding upwardly from an upper surface of the extension portion;
wherein the upper surface of the extension portion defines a lower surface of the first recess; and
wherein a side surface of the protruding portion defines a side surface of the first recess.

11. The device of claim 10, wherein the first via pattern is in contact with an upper surface of the protruding portion.

12. The device of claim 9, wherein an upper surface of the first via pattern and the upper surface of the rail pattern are coplanar.

13. The device of claim 9, wherein a lower surface of the rail pattern is spaced apart from the upper surface of the first source/drain contact.

14. The device of claim 9, further comprising:
a second source/drain contact electrically connected to a first source/drain region of the first active pattern on the other side of the gate structure; and
a second via pattern electrically connected to an upper surface of the second source/drain contact; and
wherein the second via pattern is spaced apart from the rail pattern in the second direction.

15. The device of claim 14,
wherein the second source/drain contact includes a second recess recessed more downwardly than the upper surface of the second source/drain contact; and
wherein at least a portion of the second recess extends between the second via pattern and the rail pattern.

16. The device of claim 9, further comprising:
a second active pattern extending in the first direction on the substrate and spaced apart from the first active pattern in the second direction; and
a second source/drain contact electrically connected to a second source/drain region of the second active pattern on one side of the gate structure; and
wherein the rail pattern extends between the first active pattern and the second active pattern.

17. The device of claim 16, wherein the second source/drain contact includes a second recess recessed more downwardly than the upper surface of the second source/drain contact; and wherein at least a portion of the second recess extends adjacent to the rail pattern.

18. A semiconductor device, comprising:
a first active pattern extending in a first direction across an underlying substrate;
a gate structure extending in a second direction intersecting the first direction, on the first active pattern;
a first source/drain region in the first active pattern, on both sides of the gate structure;
a first interlayer insulating film covering the gate structure and the first source/drain region, on the substrate;
a first source/drain contact that penetrates through the first interlayer insulating film on one side of the gate structure, and is electrically connected to the first source/drain region;
a second source/drain contact that penetrates through the first interlayer insulating film on the other side of the gate structure, and is electrically connected to the first source/drain region;
an etch stop layer covering an upper surface of the first interlayer insulating film, an upper surface of the first source/drain contact, and an upper surface of the second source/drain contact;
a second interlayer insulating film on the etch stop layer;
a first via pattern that penetrates through the etch stop layer and the second interlayer insulating film, and is electrically connected to the upper surface of the first source/drain contact;
a second via pattern that penetrates through the etch stop layer and the second interlayer insulating film, and is electrically connected to the upper surface of the second source/drain contact;
a first rail pattern extending in the first direction on the etch stop layer; and
a first power wiring that extends in the first direction on the second interlayer insulating film, and is electrically connected to an upper surface of the first rail pattern;
wherein the first via pattern is spaced apart from the first rail pattern in the second direction;
wherein the second via pattern is connected to a side surface of the first rail pattern;
wherein the first source/drain contact includes a first recess, which is recessed more downwardly than the upper surface of the first source/drain contact; and
wherein the second source/drain contact includes a second recess, which is recessed more downwardly than the upper surface of the second source/drain contact.

19. The device of claim 18, further comprising:
a second active pattern extending in the first direction on the substrate and spaced apart from the first active pattern in the second direction;
a second source/drain region in the second active pattern on both sides of the gate structure;
a third source/drain contact that penetrates through the first interlayer insulating film on the other side of the gate structure, and is electrically connected to the second source/drain region;
a third via pattern that penetrates through the etch stop layer and the second interlayer insulating film, and is electrically connected to an upper surface of the third source/drain contact;
a second rail pattern extending in the first direction on the etch stop layer; and
a second power wiring extending in the first direction on the second interlayer insulating film, and electrically connected to an upper surface of the second rail pattern; and
wherein the third via pattern is electrically connected to a side surface of the second rail pattern.

20. The device of claim 19, wherein the first power wiring is configured to provide a first power voltage, and the second power wiring is configured to provide a second power voltage different from the first power voltage.
